(19) United States
(12) Patent Application Publication
(10) Pub. No.: US 2016/0005480 A1
(43) Pub. Date: Jan. 7, 2016

(54) NONVOLATILE MEMORY DEVICE AND METHOD FOR OPERATING THE SAME

(71) Applicants: DONG-GUN KIM, SUWON-SI (KR); SEONG-JUN AHN, SEOUL (KR); HYUN-SEOK KIM, SEOUL (KR); YANG-WOO ROH, SEOUL (KR); SUNG-HWAN BAE, SEOUL (KR); JONG-YOUL LEE, SEOUL (KR); SE-JEONG JANG, YONGIN-SI (KR)

(72) Inventors: DONG-GUN KIM, SUWON-SI (KR); SEONG-JUN AHN, SEOUL (KR); HYUN-SEOK KIM, SEOUL (KR); YANG-WOO ROH, SEOUL (KR); SUNG-HWAN BAE, SEOUL (KR); JONG-YOUL LEE, SEOUL (KR); SE-JEONG JANG, YONGIN-SI (KR)

(21) Appl. No.: 14/788,990

(22) Filed: Jul. 1, 2015

(30) Foreign Application Priority Data
Jul. 2, 2014 (KR) 10-2014-0082475

(51) Int. Cl. G11C 16/26; G11C 16/04

(52) U.S. Cl. CPC G11C 16/26; G11C 16/0483

(57) ABSTRACT

A method for operating the 3D NAND device includes providing first and second dies and initial read levels for the first and second dies, changing the initial read level for the first die to a first read level based on a first offset that is calculated in consideration of elapsed time from a time point when a program for the first die is completed, changing the initial read level for the second die to a second read level based on a second offset that is calculated in consideration of elapsed time from a time point when a program for the second die is completed, and reading data stored in the first die using the first read level or reading data stored in the second die using the second read level.

### CROSS-REFERENCE TO RELATED APPLICATIONS

A claim of priority is made to Korean Patent Application No. 10-2014-0082475, filed on Jul. 2, 2014, in the Korean Intellectual Property Office, the disclosure of which is incorporated herein in its entirety by reference.

### BACKGROUND

The present disclosure relates to a nonvolatile memory device and a method for operating the same.

Memory devices are generally categorized as either volatile memory devices or nonvolatile memory devices depending on their ability to retain stored data in the absence of supplied power. That is, volatile memory devices are characterized by the loss of stored data when power is removed, whereas nonvolatile memory devices are characterized by the retention of stored data even when power is removed.

Examples of a nonvolatile memory device include a Read-Only Memory (ROM) and an Electrically Erasable Programmable Read-Only Memory (EEPROM).

Derived from EEPROM, the popular flash memory is characterized by performing erase operations in the units of memory blocks, and by performing operations in the units of bits.

### SUMMARY

In one aspect of the present disclosure, there is provided a method for operating a 3D NAND device. The method may include providing first and second dies and initial read levels for the first and second dies, changing the initial read level for the first die to a first read level based on a first offset that is calculated in consideration of elapsed time from a time point when a program for the first die is completed, changing the initial read level for the second die to a second read level based on a second offset that is calculated in consideration of elapsed time from a time point when a program for the second die is completed, and reading data stored in the first die using the first read level or reading data stored in the second die using the second read level.

The first die may include first and second blocks. The providing of the initial read levels may include providing the initial read levels for the first and second blocks, changing the initial read level for the first block to a third read level based on a third offset that is calculated in consideration of elapsed time from a time point when a program for the first block is completed, changing the initial read level for the second block to a fourth read level based on a fourth offset that is calculated in consideration of elapsed time from a time point when a program for the second block is completed, and reading data stored in the first block using the third read level or reading data stored in the second block using the fourth read level.

The first block may include a first memory cell layer connected to a first word line, and a second memory cell layer connected to a second word line that is separated from the first word line. The providing of the initial read levels may include providing the initial read levels for the first and second memory cell layers, changing the initial read level for the first memory cell layer to a fifth read level based on a fifth offset that is calculated in consideration of elapsed time from a time point when a program for the first memory cell layer is completed, changing the initial read level for the second memory cell array to a sixth read level based on a sixth offset that is calculated in consideration of elapsed time from a time point when a program for the second memory cell layer is completed, and reading data stored in the first memory cell layer using the fifth read level or reading data stored in the second memory cell layer using the sixth read level.

The first and second offsets may be stored in the 3D NAND device in the form of a table.

The first offset may be stored in a defect-free block that is determined to have no defect therein.

The first and second dies may be flash memory elements, and the defect-free block may be used as a Single Level Cell (SLC) mode.

The first offset may be calculated on the basis of dispersion of a threshold voltage of the first die according to elapsed time from the time point when the program for the first die is completed.

The method for operating the 3D NAND device may further comprise checking and correcting error bits of data stored in the first die, and updating the first offset if the number of accumulated error bits is equal to or larger than a predetermined value.

The method for operating the 3D NAND device may further comprise updating the first offset if the number of programs or erases of data stored in the first die is equal to or larger than a predetermined value.

The first and second offsets may be provided as metadata.

The metadata may comprise at least one parity bit.

In another aspect of the present disclosure, there is provided a method for operating the 3D NAND system The method may include providing first and second dies and initial read levels for the first and second dies, changing the initial read level for the first die to a first read level in response to a first program command that requests to program data in the first die, changing the initial read level for the second die to a second read level in response to a second program command that requests to program data in the second die, reading data stored in the first die with the first read level in response to a first read command that request to read data stored in the first die, and reading data stored in the second die with the second read level in response to a second read command that request to read data stored in the second die.

The method for operating the 3D NAND system may further comprise providing an offset for the first die. The first read level may be determined using the initial read level and the offset.

The offset may be loaded in a volatile memory to be provided.

The initial read levels of the first and second dies may be equal to each other.

### BRIEF DESCRIPTION OF THE DRAWINGS

The above and other features of the present disclosure will become apparent from the detailed description that follows, taken in conjunction with the accompanying drawings, in which:

FIG. 1 is a conceptual block diagram explaining the structure of a nonvolatile memory system according to some embodiments of the present disclosure;

FIG. 2 is a conceptual block diagram for reference in explaining an example of detailed configuration of a memory controller of FIG. 1;

FIGS. 3 to 6 are views illustrating examples of 3D-implemented nonvolatile memory device according to some embodiments of the present disclosure;

FIG. 7 is a plan view illustrating a wafer for reference in explaining dies of a nonvolatile memory device according to some embodiments of the present disclosure;

FIG. 8 is an exemplary enlarged cross-sectional view of a portion of FIG. 5;

FIG. 9 is an exemplary enlarged cross-sectional view of a portion of FIG. 8;

FIGS. 10 and 11 are graphs for reference explaining dispersion of a threshold voltage after programming of a nonvolatile memory device according to some embodiments of the present disclosure;

FIGS. 12 and 13 are exemplary views of an offset table that is used to correct a read level of a nonvolatile memory device according to some embodiments of the present disclosure;

FIG. 14 is a flowchart for reference in explaining a method for operating a nonvolatile memory device according to an embodiment of the present disclosure;

FIG. 15 is a flowchart for reference in explaining a method for operating a nonvolatile memory device according to another embodiment of the present disclosure;

FIG. 16 is a flowchart for reference in explaining a method for operating a nonvolatile memory device according to still another embodiment of the present disclosure;

FIGS. 17 and 18 are flowcharts for reference in explaining a method for operating a nonvolatile memory device according to still another embodiment of the present disclosure;

FIGS. 19 and 20 are flowcharts for reference in explaining in detail storing of an offset according to some embodiments of the present disclosure;

FIG. 21 is a block diagram of an electronic device that includes a memory controller and a nonvolatile memory device according to an embodiment of the present disclosure;

FIG. 22 is a block diagram of an electronic device that includes a memory controller and a nonvolatile memory device according to another embodiment of the present disclosure;

FIG. 23 is a block diagram of an electronic device that includes a nonvolatile memory device according to still another embodiment of the present disclosure;

FIG. 24 is a block diagram of an electronic device that includes a memory controller and a nonvolatile memory device according to still another embodiment of the present disclosure;

FIG. 25 is a block diagram of an electronic device that includes a memory controller and a nonvolatile memory device according to still another embodiment of the present disclosure; and

FIG. 26 is a block diagram of an example of a data processing system that includes the electronic device illustrated in FIG. 25.

### DETAILED DESCRIPTION OF THE EMBODIMENTS

Advantages and features of the present disclosure and methods of accomplishing the same may be understood more readily by reference to the following detailed description of preferred embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the present disclosure to those skilled in the art, and the present disclosure will only be defined by the appended claims Like reference numerals refer to like elements throughout the specification.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on”, “directly connected to” or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

Hereinafter, preferred embodiments of the present disclosure will be described with reference to the accompanying drawings.

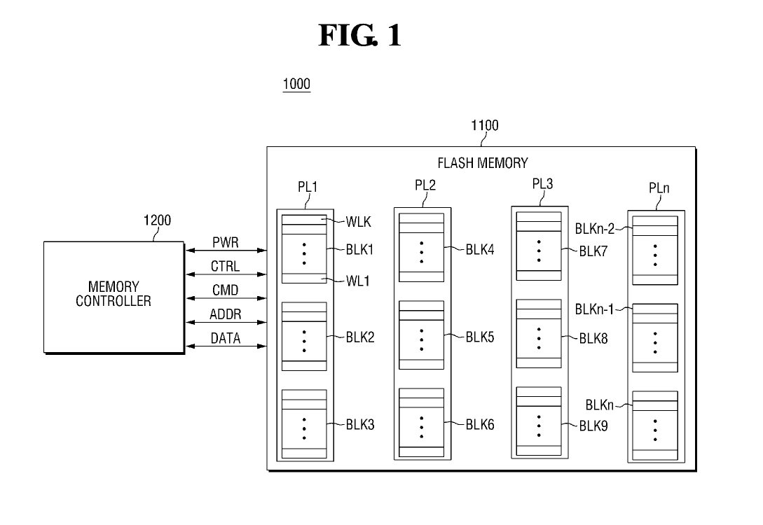

FIG. 1 is a conceptual block diagram explaining the structure of a nonvolatile memory system according to some embodiments of the present disclosure.

Referring to FIG. 1, a nonvolatile memory system 1000 according to some embodiments of the present disclosure may include a memory controller 1200 and a nonvolatile memory device 1100.

The memory controller 1200 may control the nonvolatile memory device 1100. Under the control of the memory controller 1200, the nonvolatile memory device 1100 may perform erase, write, or read operation. For this, the nonvolatile memory device 1100 may receive an input of a command CMD, an address ADDR, and data DATA through input/output lines. Further, the nonvolatile memory device 1100 may receive an input of a power PWR through a power line and an input of a control signal CTRL through a control line. The control signal CTRL may include, for example, signals of command latch enable CLE, address latch enable ALE, chip enable nCE, write enable nWE, and read enable nRE.

The memory controller 1200 may perform a program with respect to a program command for each die (chip) of the nonvolatile memory device, and in this case, the memory controller 1200 may correct a read level of each die using an offset according to elapsed time from a program completion time point. In this case, the memory controller 1200 may correct the read level before performing the read operation according to a subsequent read command using the offset that is changed according to the elapsed time from the program completion time point. The memory controller 1200 may perform the read operation with the corrected read level in response to the subsequent read command.

The nonvolatile memory device 1100 may include a flash memory, an EEPROM (Electrically Erasable Programmable Read-Only Memory), a PRAM (Ferroelectrics Random Access Memory), a PRAM (Phase-change Random Access Memory), and a MRAN (Magneto-resistive Random Access Memory), but is not limited thereto. FIG. 1 exemplarily illustrates a NAND flash memory. Referring to FIG. 1, the nonvolatile memory device 1100 may serve as a storage unit that stores data provided from the memory controller 1200. The nonvolatile memory device 1100 may include a plurality of dies that store data. Each of the plurality of dies may include a plurality of planes PL1 to PLn (where, n is a natural number). Each of the plurality of planes PL1 to PLn may include a plurality of blocks BLK1 to BLKm (where, m is a natural number), and each of the plurality of blocks BLK1 to BLKm may include a plurality of word lines WL1 to WLk (where, k is a natural number). Here, each of the plurality of blocks BLK1 to BLKm may be a unit in which an erase command is performed, that is, a unit in which erase operations are simultaneously performed. The word line may be a unit in which a program command and a read command are performed, that is, a unit in which the program operation and the read operation are simultaneously performed.

The plurality of blocks BLK1 to BLKm may include a 3D structure in which memory cells are laminated in a vertical direction from a substrate.

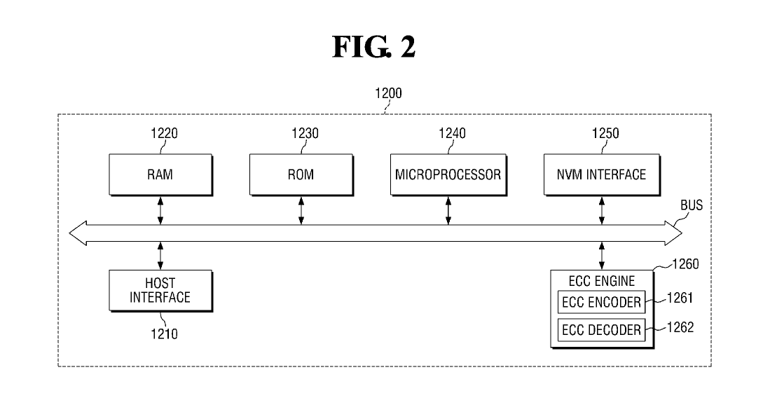

FIG. 2 is a conceptual block diagram for reference in explaining a detailed example of the configuration of a memory controller of FIG. 1. Referring to FIG. 2, a memory controller 1200 may include a host interface 1210, a RAM 1220, a ROM 1230, a microprocessor 1240, a nonvolatile memory interface 1250, and an error correction code (ECC) engine 1260. The constituent elements 1210, 1220, 1230, 1240, 1250, and 1260 may be electrically connected to each other through a bus.

The host interface 1210 may perform interfacing between the memory system 1000 including the memory controller 1200 and a host according to a predetermined protocol. The host interface 1210 may communicate with an external host through a USB (Universal Serial Bus), a SCSI (Small Computer System Interface), a PCI express, an ATA, a PATA (Parallel ATA), a SATA (Serial ATA), or a SAS (Serial Attached SCSI).

The RAM 1220 is a memory that serves as a buffer, and may store an initial command, data and various kinds of variables that are input through the host interface 1210. The RAM 1220 may also store data that is output from the nonvolatile memory device 1100. Further, the RAM 1220 may store data that is input to the nonvolatile memory device 1100, data that is output to the nonvolatile memory device 1100, various kinds of parameters and variables.

The ROM 1230 may store an operation firmware code of the memory system 1000, but the scope of the present disclosure is not limited thereto. The firmware code may be stored in the nonvolatile memory device 1100 except for the ROM 12130, for example, a NAND flash memory device.

The microprocessor 1240 may be implemented by a circuit, a logic, a code, or a combination thereof. The microprocessor 1240 may generally control the operation of the memory system 1000 including the microprocessor 1240. If the power is applied to the memory system 1000, the microprocessor 1240 may control the overall operation of the memory system 1000 by operating on the RAM 1220 the firmware for operating the memory system 1000 that is stored in the ROM 1230. Further, the microprocessor 1240 may analyze the command that is applied from the host, and may control the overall operation of the nonvolatile memory device 1100 according to the result of the analysis.

The control or intervention of the microprocessor 1240 may include not only hardwired direct control of the microprocessor 1240 but also interference of the firmware that is the software operated by the microprocessor 1240.

The nonvolatile memory interface 1250 may perform interfacing between the memory controller 1200 and the nonvolatile memory device 1100.

As illustrated in FIG. 1, a command that is controlled by the microprocessor 1240 may be provided to the nonvolatile memory device 1100 through the nonvolatile memory interface 1250, and data may be transmitted from the controller 1200 to the nonvolatile memory device 1100. Further, data that is output from the nonvolatile memory device 1100 may be provided to the controller 1200 through the nonvolatile memory interface 1250.

The ECC engine 1260 may perform an error bit correction. The ECC engine 1260 may include an ECC encoder 1261 and an ECC decoder 1262.

The ECC encoder 1261 may perform error correction encoding of data that is input through the host interface 1210 of the memory system 1000 in order to generate a codeword to which a parity bit is added. The codeword may be stored in the nonvolatile memory device 1100.

The ECC decoder 1262 may perform error correction decoding with respect to the output data, determine whether the error correction decoding has succeeded according to the result of the error correction decoding, and output an indication signal according to the result of the determination. The read data may be transmitted to the ECC decoder 1262, and the ECC decoder 1262 may correct the error bits of the data using the parity bit. If the number of error bits exceeds a correctable error bit threshold value, the ECC decoder 1262 cannot correct the error bits, and the error correction may fail.

The ECC engine 1260 may perform the error correction using coded modulation, such as an LDPC (Low Density Parity Check) code, a BCH code, a turbo code, a Reed-Solomon code, a convolution code, an RSC (Recursive Systematic Code), TCM (Trellis-Coded Modulation), or BCM (Block Coded Modulation). The ECC engine 1260 may include all of an error correction circuit, a system, and a device.

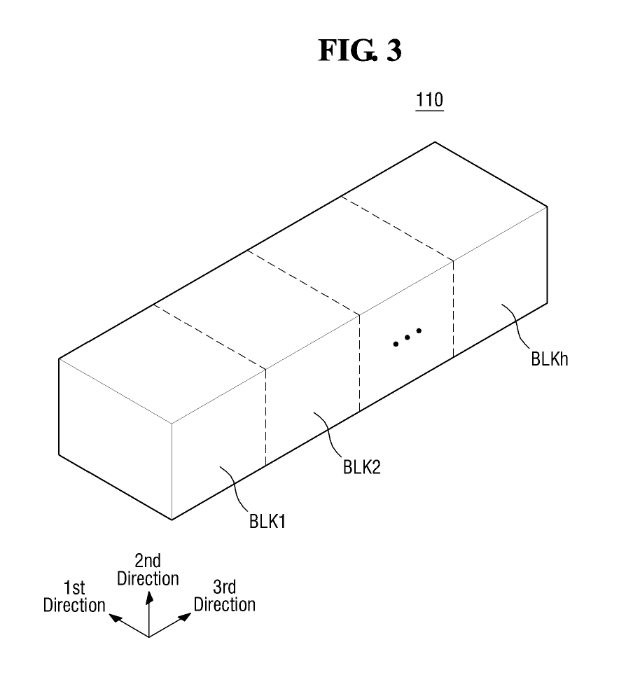

FIGS. 3 to 6 are exemplary views illustrating examples of a 3D-implemented nonvolatile memory device 1100 according to the present disclosure. FIG. 3 is a block diagram showing a memory cell array 1110 illustrated in FIG. 1. Referring to FIGS. 1 and 3, the memory cell array 1110 may include a plurality of memory blocks BLK1 to BLKh. Each of the plurality of memory blocks BLK1 to BLKh may have a 3D structure (or a vertical structure). For example, each of the plurality of memory blocks BLK1 to BLKh may include structures extended in first to third directions.

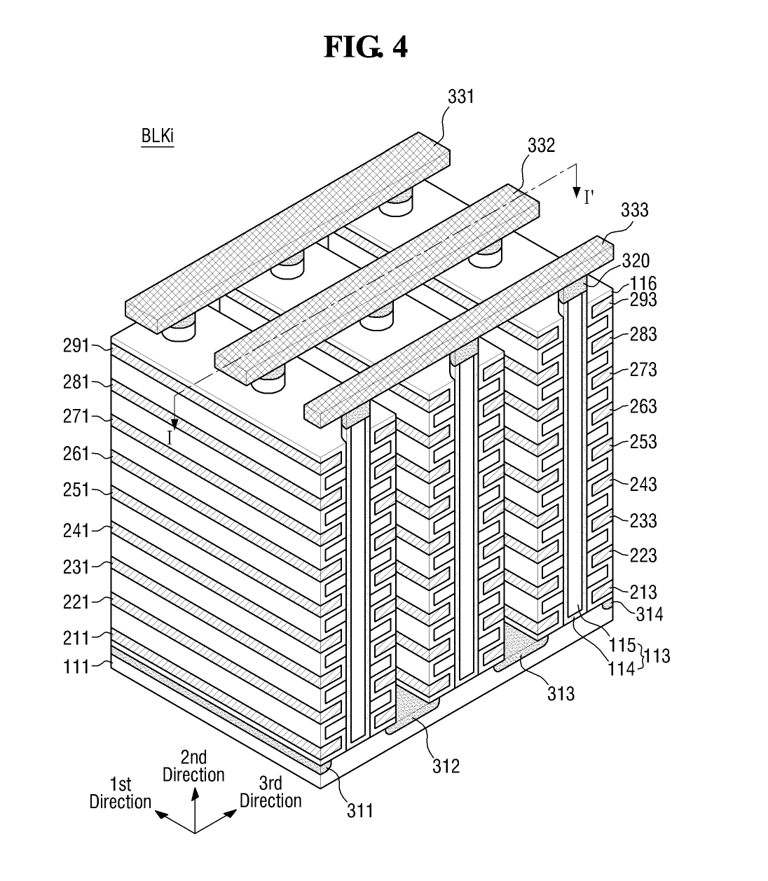

Each of the plurality of memory blocks BLK1 to BLKh may include a plurality of NAND strings NS extended in the second direction. The plurality of NAND strings NS may be provided along the first and third directions. Each of the plurality of NAND strings NS may be connected to a plurality of bit lines BL, at least one string selection line SSL, at least one ground selection line GSL, a plurality of word lines WL, at least one dummy word line DWL, and a plurality of common source lines CSL. That is, each of the plurality of memory blocks BLK1 to BLKh may be connected to the plurality of bit lines BL, a plurality of string selection lines SSL, a plurality of ground selection lines GSL, the plurality of word lines WL, a plurality of dummy word lines DWL, and the plurality of common source lines CSL. The plurality of memory blocks BLK1 to BLKh will be described in more detail with reference to FIG. 4.

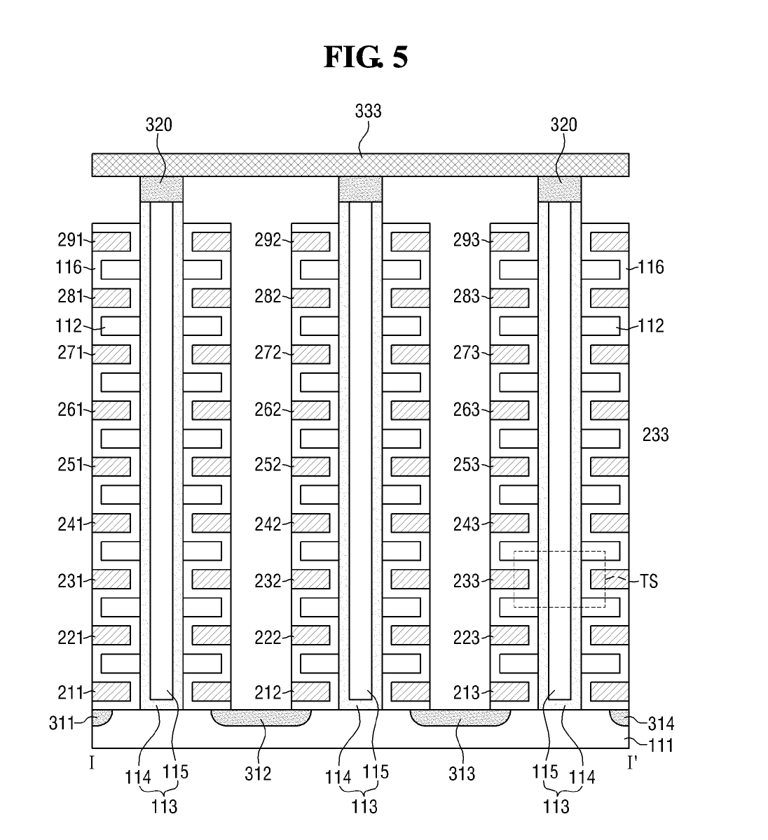

FIG. 4 is a perspective view exemplarily illustrating a memory block BLKi of FIG. 3, and FIG. 5 is a cross-sectional view of the memory block BLKi of FIG. 4 taken along line I-I′. Referring to FIGS. 4 and 5, the memory block BLKi may include structures extended along the first to third directions.

First, a substrate 111 may be provided. Exemplarily, the substrate 111 may include a silicon material doped with a first type impurity. For example, the substrate 111 may include a silicon material doped with a p-type impurity, may be a p-type well (e.g., pocket p-well), or may further include an n-type well that surrounds the p-type well. Hereinafter, it is assumed that the substrate 111 is p-type silicon. However, the substrate 111 is not limited to the p-type silicon.

A plurality of doped regions 311 to 314, which are extended along the first direction, may be provided on the substrate 111. For example, the plurality of doped regions 311 to 314 may be of a second type that is different from the type of the substrate 111. For example, the plurality of doped regions 311 to 314 may be of an n-type. Hereinafter, it is assumed that the first to fourth doped regions 311 to 314 are of an n-type. However, the type of the first to fourth doped regions 311 to 314 is not limited to the n-type.

In a region on the substrate 111 that corresponds to a region between the first and second doped regions 311 and 312, a plurality of insulating materials 112, which are extended along the first direction, may be successively provided along the second direction. For example, the plurality of insulating materials 112 and the substrate 111 may be provided to be spaced apart from each other by a predetermined distance along the second direction. Exemplarily, the insulating materials 112 may include an insulating material, such as silicon oxide.

In the region on the substrate 111 that corresponds to the region between the first and second doped regions 311 and 312, a plurality of pillars 113, which are successively arranged along the first direction, may be provided to penetrate the insulating materials 112 along the second direction. Exemplarily, the plurality of pillars 113 may be connected to the substrate 111 through penetrating of the insulating materials 112.

Exemplarily, each of the plurality of pillars 113 may be composed of a plurality of materials. For example, a surface layer 114 of each of the plurality of pillars 113 may include a silicon material doped with the first type. For example, the surface layer 114 of each of the plurality of pillars 113 may include the silicon material doped with the same type as the type of the substrate 111. Hereinafter, it is assumed that the surface layer 114 includes p-type silicon. However, the surface layer 114 of the pillar 113 is not limited to include the p-type silicon.

An inner layer 115 of each of the plurality of pillars 113 may be composed of an insulating material. For example, the inner layer 115 of each of the plurality of pillars 113 may be filled with an insulating material, such as silicon oxide.

In the region between the first and second doped regions 311 and 312, an insulating layer 116 may be provided along the insulating materials 112, the pillars 113, and an exposed surface of the substrate 111. Exemplarily, the thickness of the insulating layer 116 may be smaller than ½ of a distance between the insulating materials 112. That is, between the insulating layer 116 provided on the lower surface of the first insulating material and the insulating layer 116 provided on the upper surface of the second insulating material that is below the first insulating material among the insulating materials 112, a region in which a material other than the insulating materials 112 and the insulating layer 116 may be arranged may be provided.

The insulating layer 116 as described above may be a single layer or a multilayer.

The insulating layer 116 may include silicon oxide or insulating metal oxide having higher dielectric constant than the dielectric constant of the silicon oxide. For example, the insulating layer 116 may be formed of a multi-layer that is laminated by a high-k material, such as aluminum oxide, hafnium oxide, lanthanum oxide, tantalum oxide, titanium oxide, lanthanum hafnium oxide, lanthanum aluminum oxide, or dysprosium scandium oxide, or a combination thereof. In the drawing, it is illustrated that the insulating layer 116 is a single layer, but is not limited thereto. For example, the insulating layer 116 may be a laminated layer of silicon oxide and aluminum oxide.

In the region between the first and second doped regions 311 and 312, conductive materials 211 to 291 may be provided on the exposed surface of the insulating layer 116. For example, the conductive material 211 that is extended along the first direction may be provided between the insulating material 112 that is adjacent to the substrate 111 and the substrate 111. More specifically, the conductive material 211 that is extended in the first direction may be provided between the insulating layer 116 that is on the lower surface of the insulating material 112 adjacent to the substrate 111 and the substrate 111.

Between the insulating layer 116 provided on the upper surface of a specific insulating material and the insulating layer 116 provided on the lower surface of the insulating material arranged on the specific insulating material among the insulating materials 112, a conductive material may be provided to be extended along the first direction. Exemplarily, a plurality of conductive materials 221 to 281 that are extended in the first direction may be provided between the insulating materials 112. Further, a conductive material 291 that is extended along the first direction may be provided in regions on the insulating materials 112. Exemplarily, the conductive materials 211 to 291 that are extended in the first direction may be metal materials. Exemplarily, the conductive materials 211 to 291 that are extended in the first direction may be formed of a conductive material, such as tungsten (W), cobalt (Co), or nickel (Ni), or a semiconductor material, such as silicon, but are not limited thereto.

In the region between the second and third doped regions 312 and 313, the same structure as the structure on the first and second doped regions 311 and 312 may be provided. Exemplarily, in the region between the second and third doped regions 312 and 313, a plurality of insulating materials 112 extended in the first direction, a plurality of pillars 113 which are successively arranged along the first direction and penetrate the plurality of insulating materials 112 along the third direction, an insulating layer 116 provided on exposed surface of the plurality of insulating materials 112 and the plurality of pillars 113, and a plurality of conductive materials 212 to 202 extended along the first direction may be provided.

In the region between the third and fourth doped regions 313 and 314, the same structure as the structure on the first and second doped regions 311 and 312 may be provided. Exemplarily, in the region between the third and fourth doped regions 313 and 314, a plurality of insulating materials 112 extended in the first direction, a plurality of pillars 113 which are successively arranged along the first direction and penetrate the plurality of insulating materials 112 along the third direction, an insulating layer 116 provided on exposed surface of the plurality of insulating materials 112 and the plurality of pillars 113, and a plurality of conductive materials 213 to 293 extended along the first direction may be provided.

A plurality of drains 320 may be provided on the plurality of pillars 113. Specifically, each of the plurality of drains 320 may be provided on the corresponding pillar among the plurality of pillars 113. Exemplarily, the plurality of drains 320 may be silicon materials doped with the second type. For example, the plurality of drains 320 may be silicon materials doped with the n-type. Hereinafter, it is assumed that the plurality of drains 320 include the n-type silicon. However, the plurality of drains 320 are not limited to include the n-type silicon. Exemplarily, the width of each of the plurality of drains 320 may be larger than the width of the corresponding pillar 113. For example, each of the plurality of drains 320 may be provided on the upper surfaces of the corresponding pillar 113 in the form of a pad.

Conductive materials 331 to 333 that are extended in the third direction may be provided on the plurality of drains 320. The conductive materials 331 to 333 may be successively arranged along the first direction. Each of the conductive materials 331 to 333 may be connected to the plurality of drains 320 in the corresponding regions. Exemplarily, the plurality of drains 320 and one of the conductive materials 331 to 333 extended in the third direction may be connected to each other through contact plugs. Exemplarily, the conductive materials 331 to 333 extended in the third direction may be metal materials. Exemplarily, the conductive materials 331 to 333 extended in the third direction may be conductive materials, such as polysilicon.

Referring to FIGS. 4 and 5, each of the plurality of pillars 113 may form a string together with an adjacent region of the insulating layer 116 and an adjacent region among a plurality of conductive lines 211 to 291, 212 to 292, and 213 to 293 extended along the first direction. For example, each of the plurality of pillars 113 may form a NAND string NS together with the adjacent region of the insulating layer 116 and the adjacent region among the plurality of conductive lines 211 to 291, 212 to 292, and 213 to 293 extended along the first direction. The NAND string NS may include a plurality of transistor structures TS.

The memory block BLKi may include the plurality of pillars 113. That is, the memory block BLKi may include a plurality of NAND strings NS. More specifically, the memory block BLKi may include a plurality of NAND strings NS extended in the second direction (or in the direction that is perpendicular to the substrate).

Each of the plurality of NAND strings NS may include a plurality of transistor structures TS arranged along the second direction. At least one of the plurality of transistor structures TS in each of the plurality of NAND strings NS may operate as a string selection transistor SST. At least one of the plurality of transistor structures TS in each of the plurality of NAND strings NS may operate as a ground selection transistor GST.

Gates (or control gates) may correspond to the conductive materials 211 to 291, 212 to 292, and 213 to 293 extended along the first direction. That is, the gates (or control gates) may form word lines extended in the first direction and at least two selection lines (e.g., at least one string selection line SSL and at least one ground selection line GSL).

The conductive materials 331 to 333 extended in the third direction may be connected to one end of each of the plurality of NAND strings NS. Exemplarily, the conductive materials 331 to 333 extended in the third direction may operate as the bit lines BL. That is, in one memory block BLKi, the plurality of NAND strings NS may be connected to one bit line BL.

Second type doped regions 311 to 314 extended in the first direction may be provided to the other end of each of the plurality of NAND strings. The second type doped regions 311 to 314 extended in the first direction may operate as common source lines CSL.

In summary, the memory block BLKi may include the plurality of NAND strings NS extended in the direction (second direction) that is perpendicular to the substrate 111, and may operate as a NAND flash memory block (e.g., charge trap type) in which the plurality of NAND strings NS are connected to one bit line BL.

Referring to FIGS. 4 and 5, it is described that the conductive lines 211 to 291, 212 to 292, and 213 to 293 extended in the first direction may be provided to nine layers, but are not limited thereto. For example, the conductive lines extended in the first direction may be provided to eight lines, 16 lines, or a plurality of lines. That is, 8, 16, or a plurality of transistors may be provided in one NAND string.

Referring to FIGS. 4 and 5, it is described that three NAND strings NS are connected to one bit line BL, but are not limited thereto. Exemplarily, m NAND strings NS may be connected to one bit line BL in the memory block BLKi. In this case, the number of conductive materials 211 to 291, 212 to 292, and 213 to 293 extended in the first direction and the number of common source lines 311 to 314 may be adjusted as large as the number of NAND strings NS that are connected to one bit line BL.

Referring to FIGS. 4 and 5, it is described that three NAND strings NS are connected to one conductive material that is extended in the first direction, but are not limited thereto. For example, n NAND strings NS may be connected to one conductive material that is extended in the first direction. In this case, the number of bit lines 331 to 333 may also be adjusted as large as the number of NAND strings NS that is connected to one conductive material extended in the first direction.

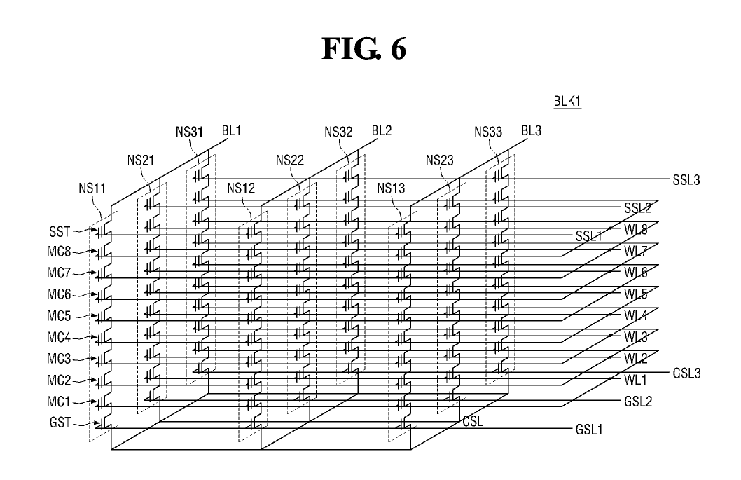

FIG. 6 is a circuit diagram illustrating an equivalent circuit of the memory block BLKi as described above with reference to FIGS. 4 and 5. Referring to FIGS. 4 to 6, NAND strings NS11 to NS31 are provided between the first bit line BL1 and the common source line CSL. The first bit line BL1 may correspond to the conductive material 331 that is extended in the third direction. NAND strings NS12, NS22, and NS32 may be provided between the second bit line BL2 and the common source line CSL. The second bit line BL2 may correspond to the conductive material 332 that is extended in the third direction. NAND strings NS13, NS23, and NS33 may be provided between the third bit line BL3 and the common source line CSL. The third bit line BL3 may correspond to the conductive material 333 that is extended in the third direction.

String selection transistors SST of each of the plurality of NAND strings NS may be connected to the corresponding bit line BL. Ground selection transistors GST of each of the plurality of NAND strings NS may be connected to the common source line CSL. Memory cells MC may be provided between the string selection transistors SST and the ground selection transistors GST of each of the plurality of NAND strings NS.

Hereinafter, NAND strings NS are defined in the unit of rows and columns. The NAND strings NS that are commonly connected to one bit line may form one column. For example, the NAND strings NS11 to NS 31 connected to the first bit line BL1 may correspond to the first column. The NAND strings NS12 to NS32 connected to the second bit line BL2 may correspond to the second column. The NAND strings NS13 to NS33 connected to the third bit line BL3 may correspond to the third column. The NAND strings NS connected to one string selection line SSL may form one row. For example, the NAND strings NS11 to NS13 connected to the first string selection line SSL1 may form the first row. The NAND strings NS21 to NS23 connected to the second string selection line SSL2 may form the second row. The NAND strings NS31 to NS33 connected to the third string selection line SSL3 may form the third row.

The height of each NAND string NS is defined. Exemplarily, the height of a memory cell MC1 that is adjacent to a ground selection transistor GST in the NAND string NS may be “1”. The height of the memory cell may become increased as the memory cell becomes adjacent to the string selection transistor SST in the NAND string NS. The height of the memory cell MC7 that is adjacent to the string selection transistor SST in the NAND string NS may be “7”.

The string selection transistors SST of the NAND strings NS in the same row may share the string selection line SSL. At the same height, word lines connected to memory cells MC of the NAND strings NS in different rows may be commonly connected. The word line WL means a memory cell layer. The ground selection transistors GST of the NAND strings NS in the same row may share the ground selection line GSL. The ground selection transistors GST of the NAND strings NS in different rows may share the ground selection line GSL. That is, the NAND strings NS11 to NS13, NS21 to NS23, and NS31 to NS33 may be commonly connected to the ground selection line GSL. Accordingly, the management of a word line that includes a bad memory cell as a bad region may correspond to the management of a memory layer that includes a bad memory cell as a bad region.

The common source line CSL may be commonly connected to the NAND strings NS. For example, in an active region on the substrate 111, the first to fourth doped regions 311 to 314 may be connected. For another example, the first to fourth doped regions 311 to 314 may be connected to an upper layer through a contact. The first to fourth doped regions 311 to 314 may be commonly connected on the upper layer.

As illustrated in FIG. 6, the word lines WL that are memory cell layers connecting the memory cells at the same height may be commonly connected. Accordingly, when a specific word line WL is selected, all NAND strings NS connected to the specific word line WL may be selected. The NAND strings NS in the different rows may be connected to different string selection lines SSL. Accordingly, by selecting the string selection lines SSL1 to SSL3, the NAND strings NS in the non-selected rows among the NAND strings NS connected to the same word line WL may be separated from the bit lines BL1 to BL3. That is, by selecting the string selection lines SSL1 to SSL3, the row of the NAND strings NS may be selected. Further, by selecting the bit lines BL1 to BL3, the NAND strings NS in the selected rows may be selected in the unit of a column.

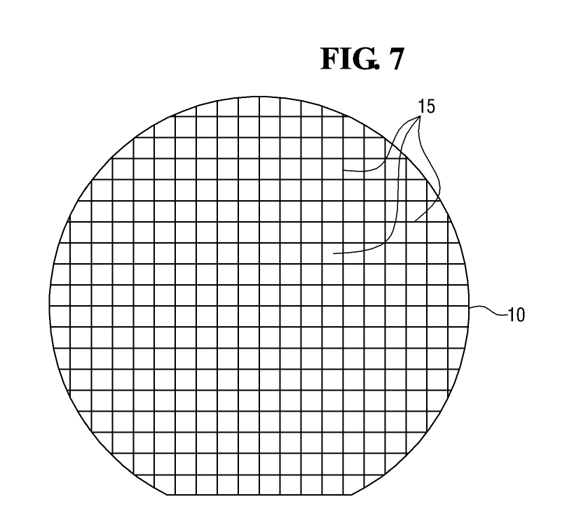

FIG. 7 is a plan view illustrating a wafer for reference in explaining dies of a nonvolatile memory device according to some embodiments of the present disclosure.

Referring to FIG. 7, a semiconductor wafer 10 may include a plurality of semiconductor dies 15. The plurality of semiconductor dies 15 may be manufactured by separating the semiconductor wafer 10 into a plurality of parts. The nonvolatile memory system according to an embodiment of the present disclosure may be manufactured using the plurality of semiconductor dies 15.

Referring again to FIGS. 1 and 7, the nonvolatile memory device 1100 may include the plurality of semiconductor dies 15 for storing data. Each of the plurality of semiconductor dies 15 may include a plurality of plains PL1 to PLn (where, n is a natural number). Each of the plurality of plains PL1 to PLn may include a plurality of blocks BLK1 to BLKm (where, m is a natural number), and each of the plurality of blocks BLK1 to BLKm may include a plurality of word lines WL1 to WLk (where, k is a natural number). Here, each of the plurality of blocks BLK1 to BLKm may be a unit in which an erase command is performed, that is, a unit in which erase operations are simultaneously performed. The word line may be a unit in which a program command and a read command are performed, that is, a unit in which a program operation and a read operation are simultaneously performed.

The plurality of semiconductor dies 15 of the nonvolatile memory device 110 may have different manufacturing processes and different positions in the wafer. The plurality of semiconductor dies 15 may have different characteristics. Accordingly, each of the plurality of dies 15 may have different read level characteristics.

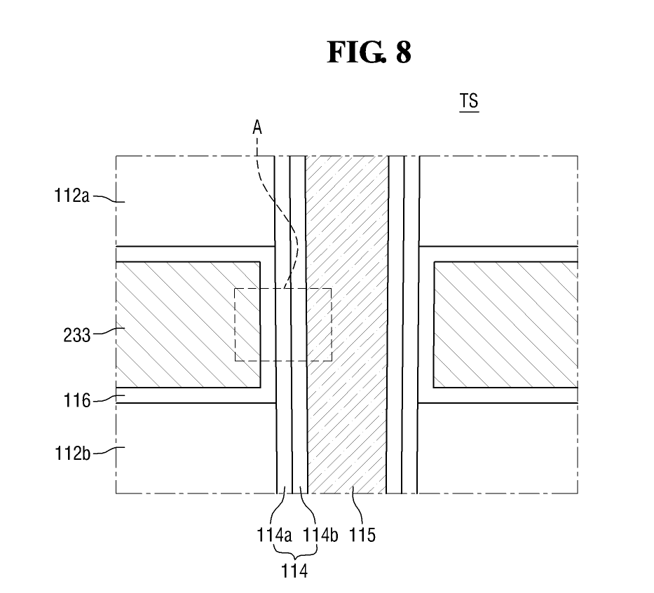

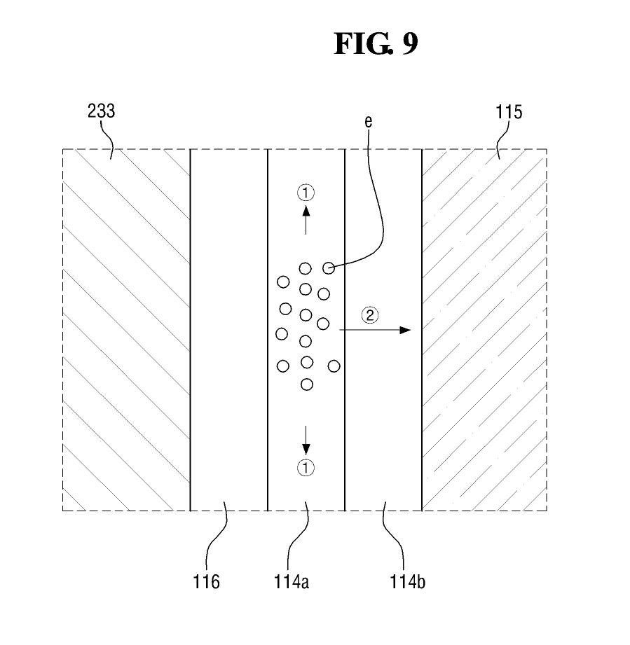

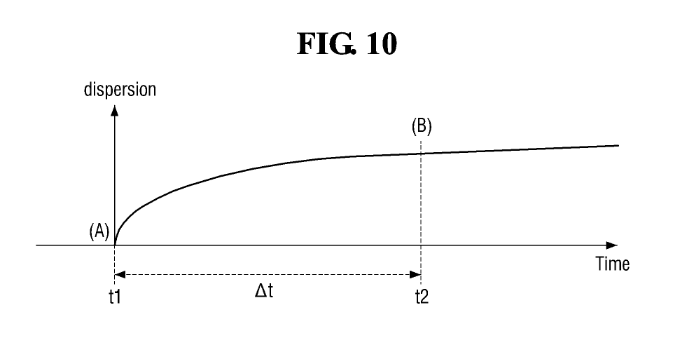

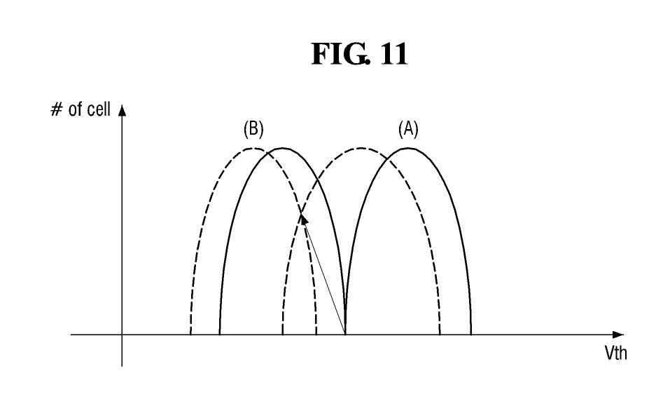

FIG. 8 is an exemplary enlarged cross-sectional view of a portion (TS) of FIG. 5, and FIG. 9 is an exemplary enlarged cross-sectional view of a portion (A) of FIG. 8. FIGS. 10 and 11 are graphs for reference in explaining dispersion of a threshold voltage after programming of a nonvolatile memory device according to some embodiments of the present disclosure.

Referring to FIG. 8, in a nonvolatile memory device according to an embodiment of the present disclosure, a surface layer 114 of each pillar 113 may include a trap layer 114a and a tunnel layer 114b. The trap layer 114a, the tunnel layer 14b, and the insulating layer 116 may be formed between an insulating material 112a arranged on an upper side and a conductive material 233, between an insulating material 112b arranged on a lower side and the conductive material 233, or between an inner layer 115 (or trap layer 114a) and the conductive material. That is, the trap layer 114a, the tunnel layer 114b, and the insulating layer 116 may be conformally formed according to the shapes of the insulating materials 112a and 112b and the inner layer 115.

The tunnel layer 114b may be a portion through which charge passes, and may be formed of, for example, a silicon oxide layer or a double layer of silicon oxide and silicon nitride.

The trap layer 114a may be a portion where the charge that has passed through the tunnel layer 114b is stored. For example, the trap layer 114a may be formed of a nitride layer or a high-k layer. The nitride layer may include, for example, at least one of silicon nitride, silicon oxynitride, hafnium oxynitride, zirconium oxynitride, hafnium silicon oxynitride, and hafnium aluminum oxynitride. The high-k layer may include, for example, at least one of hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

Referring to FIG. 9, according to the nonvolatile memory device according to an embodiment of the present disclosure, charge e may be stored in the trap layer 114a that is a non-conductive memory layer by a program using a CTF (Charge Trap Flash) method. The stored charge e may move in direction circle-1 or circle-2 as the time passes by. This may occur due to a rearrangement phenomenon or a channel loss, and is called a fast charge loss phenomenon.

Referring to FIG. 10, due to the fast charge loss phenomenon, the dispersion of a threshold voltage of a cell may droop and spread. In FIG. 10, the horizontal axis indicates time, and the vertical axis indicates spreading of the dispersion of the threshold voltage. Here, t1 is a program time when the dispersion of the threshold voltage is positioned in the trap layer 114a. After a predetermined time elapses, that is, at time t2, the dispersion of the threshold voltage may droop and spread. The difference Δt between t2 and t1 means elapsed time from a time point when the program is completed. The time may also be a retention time. The read level may be changed according to the retention time.

Referring to FIG. 11, the position of a valley between the dispersions may be changed from (A) to (B) according to the retention time (see an arrow in FIG. 11). Accordingly, if the read level for reading the position of the valley is not corrected, data read may not be properly performed. FIG. 11 illustrates a Multi-Level Cell (MLC) mode in which two dispersions of the threshold voltage exist, but is not limited thereto. There may be a Single Level Cell (SLC) mode in which one dispersion of the threshold voltage exists or a Triple Level Cell (TLC) mode in which three dispersions of the threshold voltage exist.

Referring again to FIGS. 1 and 7, the dispersions of the threshold voltage may have different change characteristics according to the plurality of semiconductor dies 15. That is, the dispersions of the threshold voltage of different semiconductor dies 15 may have different change amounts and shapes depending on the retention time. Accordingly, in case of uniformly correcting the read level of the whole nonvolatile memory device 1100 without correcting the respective read levels according to the semiconductor dies 15, reliability of an operation of the nonvolatile memory device 1100 may be decreased.

Accordingly, an offset for correcting the read level by dies may differ. The offset may be provided to the nonvolatile memory device 1100 with an initial read level. Specifically, the offset may be stored in the nonvolatile memory device 1100. The offset may be stored in the form of a table. The offset table may include offset information for the dies. Since the offset table includes offset information for the dies, the read level can be subsequently corrected by dies.

The offset may be provided with the initial read level. The initial read level may be the same by dies. However, the initial read level is not limited thereto, but the initial read level may differ by dies. The offset may differ by dies.

The offset may be determined by programming and actually measuring the dispersion of the threshold voltage. Accordingly, the determination of the offset may be performed in the process of manufacturing the nonvolatile memory device 1100, but is not limited thereto. The determination or update of the offset may be performed even during a run-time when the nonvolatile memory device 110 is in use.

The offset table may be stored in a defect-free block of the nonvolatile memory device. The defect-free block means a block that is determined to have no defect during a defect test among the blocks of the nonvolatile memory device 1100. In general, the nonvolatile memory device 1100 can pass the defect test not only in case that the entire blocks have no defect but also in case that only a defect of which the ratio is equal to or lower than a predetermined ratio is found during the defect test. However, the defect-free region may be a portion that does not have even one bit of defect during the test. Accordingly, by storing the offset table in the defect-free block, the possibility that an error occurs when the offset table is loaded or applied can be decreased, and thus the stability in correcting the read level can be further enhanced.

The nonvolatile memory device 1100 may be a flash memory, and the region where the offset table is stored may be used as the SLC mode. That is, in case of a flash memory, the SLC, MLC, or TLC mode can be used. In case of the SLC mode, only on/off states of one bit can be discriminated, and in case of the MLC mode, four states of two bits can be discriminated. Further, in case of the TLC mode, eight states of three bits can be discriminated. However, the SLC mode may have higher stability and higher speed compared with the MLC mode. Accordingly, the stability of the offset table can be further enhanced through storing of the offset table in a region that is used as the SLC mode.

In another embodiment of the present disclosure, the offset may not be simply classified by dies, but the offset may be provided by blocks included in the die, and the read level may be corrected by blocks. Further, the offset may be provided by word lines included in the block, that is, by memory cell layers, and the read level may be corrected by memory cell layers. In this case, more accurate read operation can be performed. However, in case of the memory cell array, calculation may be possible only through slight deviation, and thus collective correction may be performed without providing a new separate offset. In this case, the operation amount can be reduced.

In case of correcting the read level by blocks as described above, different read levels may be provided by blocks, but are not limited thereto. Further, in case of correcting the read level by word lines as described above, different read levels may be provided by the word lines, but are not limited thereto.

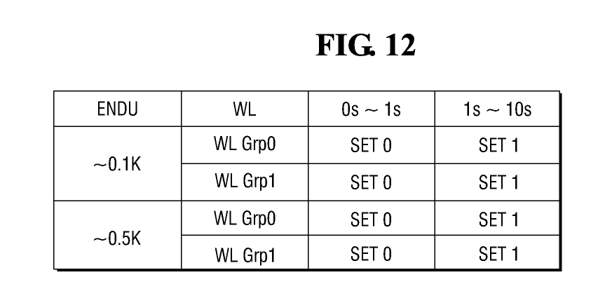

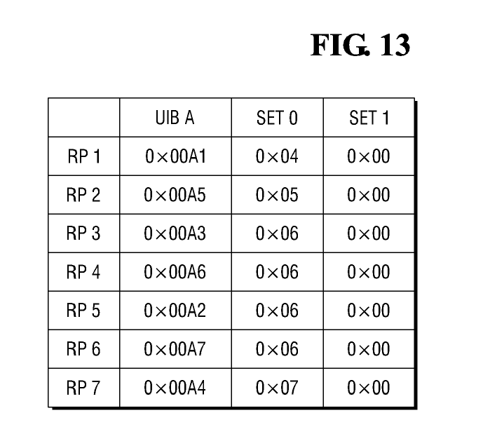

FIGS. 12 and 13 are exemplary views of an offset table that is used to correct a read level of a nonvolatile memory device according to some embodiments of the present disclosure.

Referring to FIG. 12, the offset table may be in the form of a Charge Loss Table (CLT). That is, endurances may be classified by dies (first column of the table), and then may be classified by word lines (second column of the table) as described above. FIG. 12 illustrates the classification by the word lines. However, this is merely exemplary, and the classification may be performed by dies or blocks.

The third and fourth columns of the table in FIG. 12 may indicate the offsets according to the retention time. That is, the CLT may be a data table provided through measurement of dispersion of actual threshold voltages according to the retention time from the program completion time.

Referring to FIG. 13, the CLT may be stored in the nonvolatile memory device 1100 as metadata. Since the CLT is the metadata, loading of the offset for correcting the read level may become faster. The offset table that is the metadata may be in the form of a Read Level Table (RLT), but is not limited thereto. The offset data may be stored and applied fast by dies, blocks, or word lines.

The metadata may be metadata of firmware of the nonvolatile memory device. In this case, the metadata may be stored together with a parity bit to enhance the stability of the offset table and the access efficiency of the table.

Referring again to FIG. 1, during booting of the nonvolatile memory device 1100, the offset data may be loaded onto a volatile memory. The volatile memory may be a Dynamic Random Access Memory (DRAM). In this case, the offset data can be used at a speed that is much higher than the speed in case of loading the offset data onto a general memory, but is not limited thereto.

Hereinafter, referring to FIGS. 1, 2, and 12 to 20, a method for operating a nonvolatile memory device according to some embodiments of the present disclosure will be described. The duplicate portions to those as described above will be simplified or omitted.

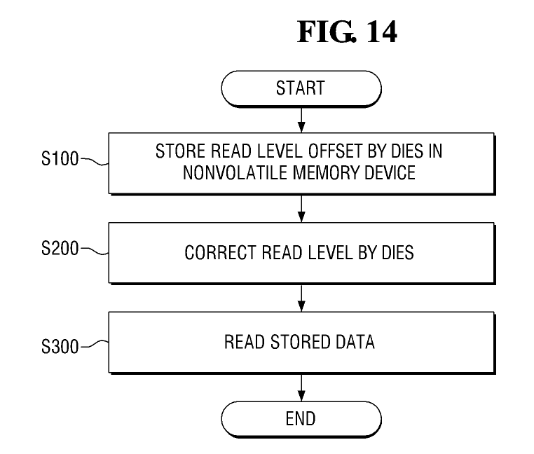

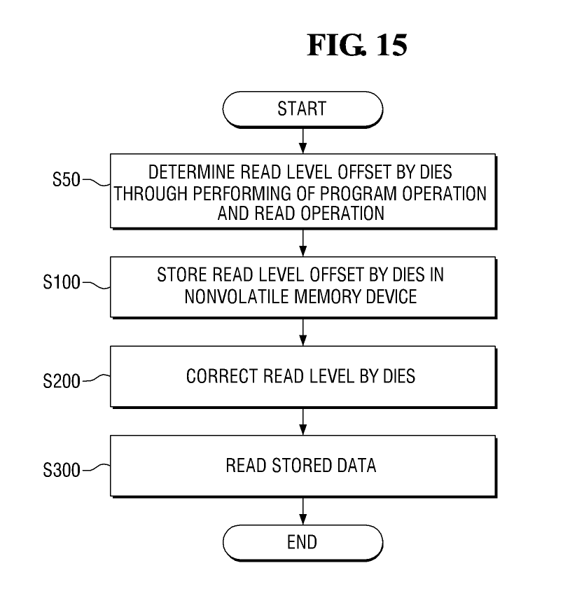

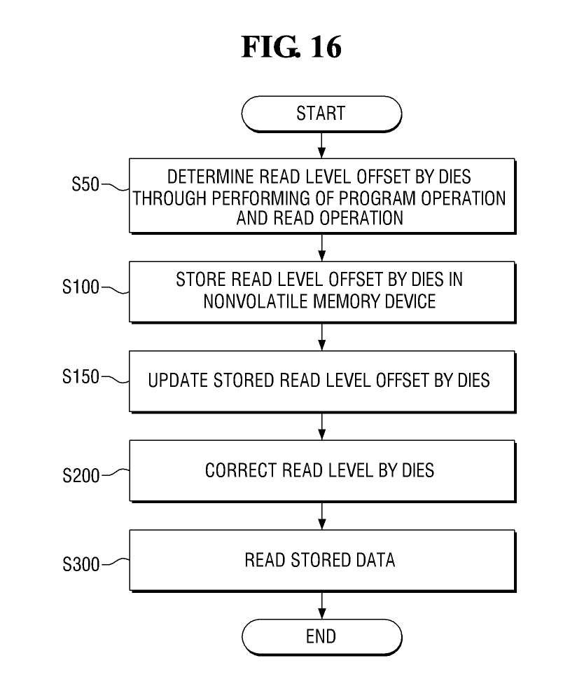

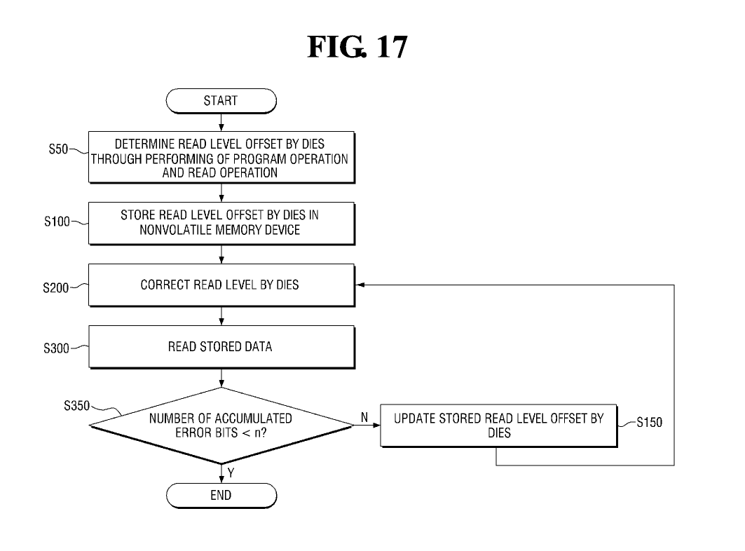

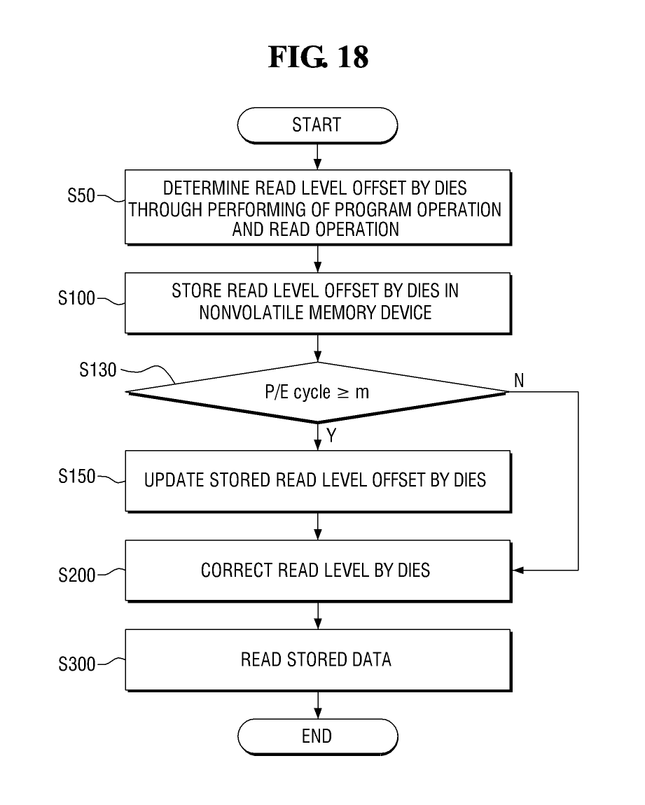

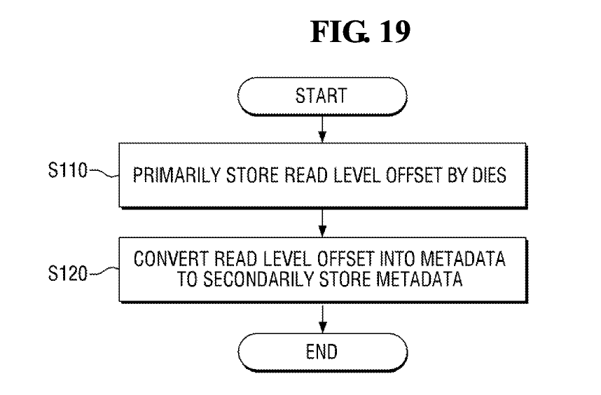

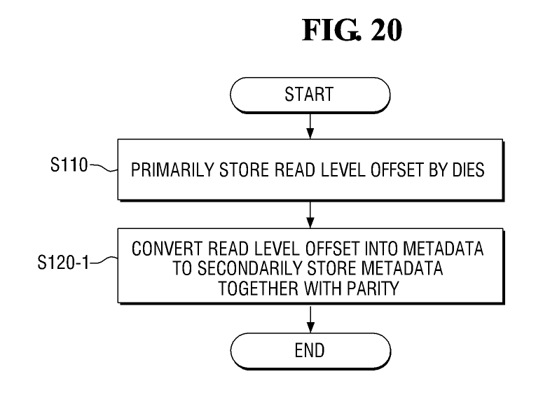

FIG. 14 is a flowchart explaining a method for operating a nonvolatile memory device according to an embodiment of the present disclosure, FIG. 15 is a flowchart explaining a method for operating a nonvolatile memory device according to another embodiment of the present disclosure, and FIG. 16 is a flowchart explaining a method for operating a nonvolatile memory device according to still another embodiment of the present disclosure. FIGS. 17 and 18 are flowcharts explaining a method for operating a nonvolatile memory device according to still another embodiment of the present disclosure, and FIGS. 19 and 20 are flowcharts explaining in detail storing of an offset according to some embodiments of the present disclosure.

Referring to FIG. 14, offsets by dies may be stored (S100).

The offsets by dies may be stored in a defect-free region of the nonvolatile memory device. Further, the offsets may be stored in the form of a table. The offsets may be stored in a region that is used as the SLC mode. Through this, the stability of the offset table can be further enhanced. The offsets by dies may be changed according to the retention time that elapses from a program time point, and may be stored by dies according to the degree of the change, but are not limited thereto. The offsets may be stored by blocks or word lines in addition to by dies.

Then, the read level may be corrected by dies (S200).

The read level may be changed differently by dies, and may be corrected according to the offsets. In this case, the read level may be corrected through addition of the offset to the initial read level, but is not limited thereto.

The correction of the read level may be performed by dies, but is not limited thereto. The correction of the read level may be performed by blocks included in the die. Further, the correction of the read level may be further performed by memory cell layers included in the block, that is, by word lines.

The degree of the correction may differ depending on the retention time that is the elapsed time from the program completion time point. That is, the provided offset itself may be changed according to the retention time.

The correction may not be performed every time during reading. That is, the nonvolatile memory device may continue reading if necessary, but the correction may not be necessarily accompanied by such reading. Then, the stored data may be read (S300).

The stored data may be read according to the corrected read level. In this case, the problem that is caused by the fast charge loss phenomenon according to the retention time can be solved to perform correct reading.

The reading of the stored data may be performed multiple times. That is, the read operation may be performed several times without additional correction after the read level is corrected. Accordingly, the reading of the stored data may include both reading of the stored data through correction of the read level and reading of the stored data without correction of the read level with respect to the reading of the previous data.

Referring to FIGS. 1 and 15, a method for operating a nonvolatile memory device according to another embodiment of the present disclosure may further include one step before storing the offsets by dies.

That is, the offset by dies may be determined through performing of a program operation and a read operation (S50).

The offset determination may be performed in the process of manufacturing the nonvolatile memory device 1100, but is not limited thereto. That is, the manufacturing process may be a NAND package manufacturing process or a Solid State Drive (SSD) assembling process in case that the nonvolatile memory device 1100 is a SSD, but is not limited thereto. That is, the offset determination may be performed by measuring the dispersion of the threshold voltage according to the retention time through performing of the program and the read. The dispersion of the threshold voltage according to the retention time may be categorized in a predetermined range. Accordingly, the offset may be determined by evaluating what category the dies belong to and selecting the offset that corresponds to the category, but is not limited thereto.

The offset determination may be performed through dedicated software. Specifically, since the offset determination is to find an optimum value, various methods may be provided, and a method for finding the same may be acquired through the dedicated software, but is not limited thereto.

Referring to FIGS. 1, and 16 to 18, a method for operating a nonvolatile memory device according to still another embodiment of the present disclosure may further include one step before correcting the read level.

That is, the offset by dies may be updated (S150).

The offset update may be performed during the run-time. As the time passes by after the nonvolatile memory device is manufactured, the read level characteristics may be changed. Accordingly, the previously determined offset may differ from the characteristics of the current device. In order to correct this, a new offset may be necessary, and update of the offset may be necessary. Such update may be performed under specific conditions. Hereinafter, referring to FIGS. 1, 2, 17, and 18, the specific conditions will be described.

Referring to FIGS. 1, 2, and 17, after the stored data is read (S300), it is determined whether the number of error bits is equal to or larger than a predetermined number n. If the number of error bits is equal to or larger than the predetermined number, the offset may be updated (S350).

The ECC engine 1260 may perform error bit correction. The ECC engine 1260 may include an ECC encoder 1261 and an ECC decoder 1262. The ECC engine 1260 may count the number of error bits while correcting the error bits. If the number of error bits is equal to or larger than the predetermined number n (in FIG. 17), the offset may be updated (S150). This is because the number of error bits may be determined as a parameter indicating that the characteristics of the nonvolatile memory device 1100 are changed.

Then, the read level may be corrected by dies on the basis of the updated offset (S200), and then the stored data may be read again on the basis of the corrected read level (S300). The reading of the stored data may be performed multiple times. That is, the read operation may be performed several times without additional correction after the read level is corrected. Accordingly, the reading of the stored data may include both the reading of the stored data after correction of the read level and the reading of the stored data without correction of the read level with respect to the reading of the previous data.

Referring to FIGS. 1 and 18, it is determined whether a P/E cycle is equal to or larger than a predetermined number of times m. If the P/E cycle is equal to or larger than the predetermined number of times m, the offset may be updated (S130).

Since the P/E cycle means the number of times the program operation and the erase operation are performed, it may be determined by the number of programs and the number of erases. The number of the P/E cycles may be counted by the memory controller 1200. If the number of P/E cycles is equal to or larger than the predetermined number m (in FIG. 18), the update of the offset may be performed. This is because the number of P/E cycles may be determined as a parameter indicating that the characteristics of the nonvolatile memory device 1100 are changed.

Referring to FIGS. 12, 13, and 19, storing the offset by dies (S100) may be sub-divided.

First, the offset by dies may be primarily stored (S110).

The primary storing may store the offset in the form of a table, but is not limited thereto. The primary storing may be storing of the offset in the form of a CLT of FIG. 12.

Then, the offset may be converted into metadata for secondary storing thereof (S120).

That is, the metadata may be metadata of firmware of the nonvolatile memory device. The metadata may be stored in the form of an RLT of FIG. 13. Through the storing of the metadata, the stability of the offset table and the access efficiency of the offset table can be enhanced.

However, such steps may not be essential, but are merely exemplary.

Referring to FIG. 20, the secondary storing (S120) may be changed.

That is, the offset may be converted into metadata and may be secondarily stored together with the parity bit (S120-1).

The offset may be stored together with the parity bit for an error check of the offset. In this case, the error of the offset data may be firstly checked to reduce the error of the offset data and to enhance reliability.

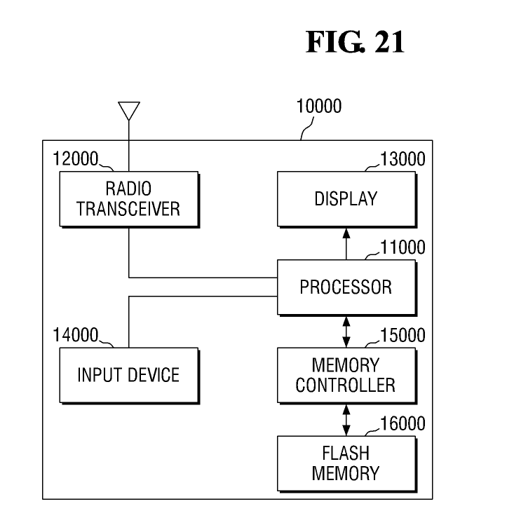

FIG. 21 is a block diagram of an electronic device 10000 that includes a memory controller 15000 and a nonvolatile memory device 16000 according to an embodiment of the present disclosure.

Referring to FIG. 21, an electronic device 10000, such as a cellular phone, a smart phone, or a tablet PC, may include a nonvolatile memory device 16000 that may be implemented by a flash memory device and a memory controller 15000 that can control the operation of the nonvolatile memory device 16000.

The nonvolatile memory device 16000 may be the nonvolatile memory device 1100 illustrated in FIG. 1. The nonvolatile memory device 16000 may store random data.

The memory controller 15000 may be controlled by a processor 11000 that controls the overall operation of the electronic device.

Data that is stored in the nonvolatile memory device 16000 may be displayed through a display 13000 under the control of the memory controller 15000 of which the operation is controlled by the processor 11000.

A radio transceiver 12000 may transmit or receive a radio signal through an antenna ANT. For example, the radio transceiver 12000 may convert the radio signal that is received through the antenna ANT into a signal that can be processed by the processor 11000. Accordingly, the processor 11000 may process the signal that is output from the radio transceiver 12000, and may store the processed signal in the nonvolatile memory device 16000 through the memory controller 15000 or display the processed signal through the display 13000.

The radio transceiver 12000 may convert the signal that is output from the processor 11000 into a radio signal, and may output the converted radio signal to an outside through the antenna ANT.

An input device 14000 may be a device that can input a control signal for controlling the operation of the processor 11000 or data to be processed by the processor 11000. The input device 14000 may be implemented by a touch pad, a pointing device such as a computer mouse, a keypad, or a keyboard.

The processor 11000 may control the display 13000 to display the data that is output from the nonvolatile memory device 16000, the radio signal that is output from the radio transceiver 12000, or the data that is output from the input device 14000 there through.

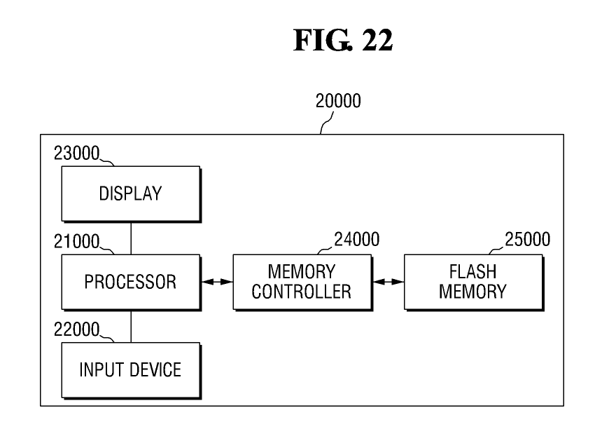

FIG. 22 is a block diagram of an electronic device 20000 that includes a memory controller 24000 and a nonvolatile memory device 25000 according to another embodiment of the present disclosure.

Referring to FIG. 22, an electronic device 20000, which may be implemented by a data processing device, such as a PC (Personal Computer), a tablet computer, a net-book, an e-reader, a PDA (Personal Digital Assistant), a PMP (Portable Multimedia Player), an MP3 player, or an MP4 player, may include a nonvolatile memory device 25000 such as a flash memory device and a memory controller 24000 that can control the operation of the nonvolatile memory device 25000.

The nonvolatile memory device 25000 may be the nonvolatile memory device illustrated in FIGS. 1 and 21. The nonvolatile memory device 25000 may store random data.

The electronic device 20000 may include a processor 21000 that controls the overall operation of the electronic device 20000. The memory controller 24000 may be controlled by the processor 21000.

The processor 21000 may display the data that is stored in the nonvolatile memory device through a display according to an input signal generated by an input device 22000. For example, the input device 22000 may be implemented by a touch pad, a pointing device such as a computer mouse, a keypad, or a keyboard.

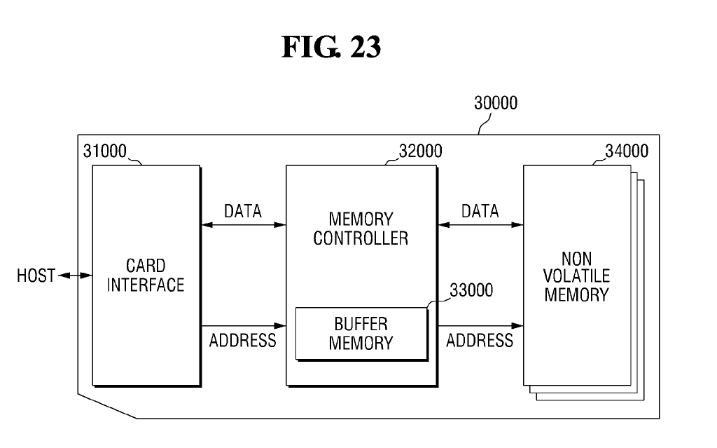

FIG. 23 is a block diagram of an electronic device 30000 that includes a nonvolatile memory device 34000 according to still another embodiment of the present disclosure.

Referring to FIG. 23, an electronic device 30000 may include a card interface 31000, a memory controller 32000, and a nonvolatile memory device 34000, for example, a flash memory.

The electronic device 30000 may transmit or receive data with a host HOST through a card interface 30000. According to an embodiment, the card interface 31000 may be a Secure Digital (SD) card interface or a Multi-Media Card (MMC) interface, but is not limited thereto. The card interface 31000 can interface a data exchange between the host HOST and the memory controller 32000 according to a communication protocol of the host HOST that can communicate with the electronic device 30000.

The memory controller 32000 may control the overall operation of the electronic device 30000, and may control the data exchange between the card interface 31000 and the nonvolatile memory device 34000. Further, a buffer memory 325 of the memory controller 32000 may buffer data that is transmitted or received between the card interface 31000 and the nonvolatile memory device 34000.

The memory controller 32000 may be connected to the card interface 31000 and the nonvolatile memory device 34000 through a data bus DATA and an address bus ADDRESS. According to an embodiment, the memory controller 32000 may receive an address of the data to be read or written from the card interface 31000 through the address bus ADDRESS, and may transmit the address to the nonvolatile memory device 34000.

Further, the memory controller 32000 may receive or transmit the data to be read or written through the data bus DATA connected to the card interface 31000 or the nonvolatile memory device 34000.

The nonvolatile memory device 34000 may be the nonvolatile memory device illustrated in FIG. 1. The nonvolatile memory device 16000 may store random data.

When the electronic device 30000 of FIG. 23 is connected to the host HOST, such as a PC, a tablet PC, a digital camera, a digital audio player, a cellular phone, console video game hardware, or a digital set-top box, the host HOST may transmit or receive the data stored in the nonvolatile memory device 34000 through the card interface 31000 and the memory controller 32000.

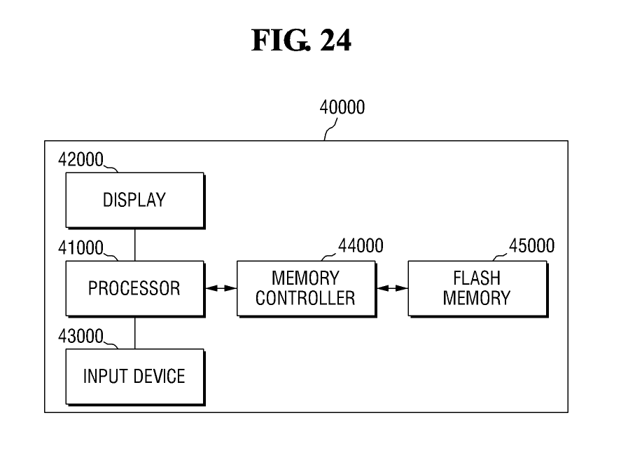

FIG. 24 is a block diagram of an electronic device that includes a memory controller and a nonvolatile memory device according to still another embodiment of the present disclosure.

Referring to FIG. 24, an electronic device 40000 may include a nonvolatile memory device 45000 such as a flash memory, a memory controller 44000 that controls a data processing operation of the nonvolatile memory device 45000, and an image sensor 41000 that can control the overall operation of the electronic device 40000.

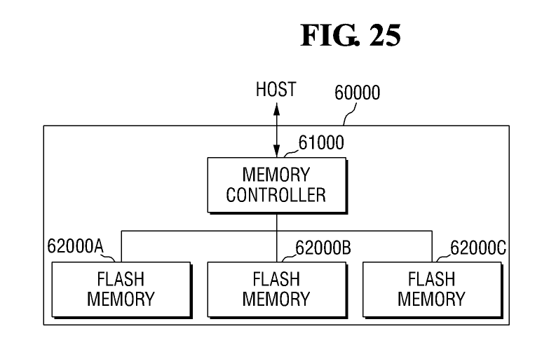

The nonvolatile memory device 45000 may be the nonvolatile memory device illustrated in FIGS. 1 and 25.

The image sensor 42000 of the electronic device 40000 may convert an optical signal into a digital signal. The converted digital signal may be stored in the nonvolatile memory device 45000 under the control of the image sensor 41000 or may be displayed through a display 43000. Further, the digital signal that is stored in the nonvolatile memory device 45000 may be displayed through the display 43000 under the control of the image sensor 41000.

FIG. 25 is a block diagram of an electronic device 60000 that includes a memory controller 61000 and nonvolatile memory devices 62000A, 62000B, and 62000C according to still another embodiment of the present disclosure.

Referring to FIG. 25, the electronic device 60000 may be implemented by a data storage device such as a Solid State Drive (SSD).

The electronic device 60000 may include a plurality of nonvolatile memory devices 62000A, 62000B, and 62000C, and a memory controller 61000 that can control data processing operation of the plurality of nonvolatile memory devices 62000A, 62000B, and 62000C.

The electronic device 60000 may be implemented by a memory system or a memory module.

The nonvolatile memory device 62000 may be the nonvolatile memory device illustrated in FIGS. 1 and 25. The nonvolatile memory device 62000 may store random data.

According to an embodiment, the memory controller 61000 may be implemented inside or outside the electronic device 60000.

The nonvolatile memory device 62000 may include a plurality of dies, and may correct the read level in response to a program command for each die of the host. Further, the nonvolatile memory device 16000 may read data of each die with the corrected read level in response to the read command for each die of the host.

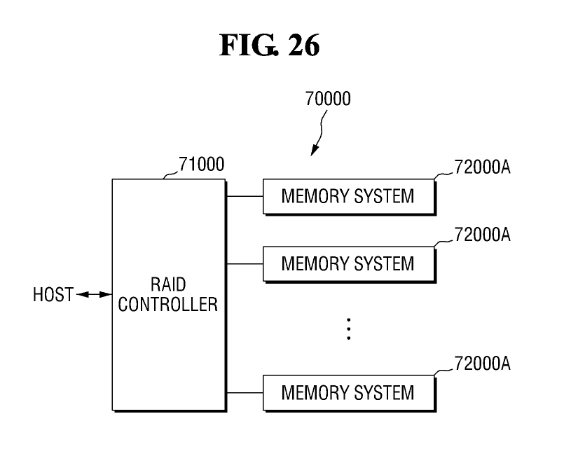

FIG. 26 is a block diagram of an example of a data processing system that includes the electronic device illustrated in FIG. 25.

Referring to FIGS. 25 and 26, a data storage device 70000 that can be implemented by a Redundant Array of Independent Disks (RAID) system may include a RAID controller 71000 and a plurality of memory systems 72000A and 72999B to 72000N (where, N is a natural number).

The plurality of memory systems 72000A and 72999B to 72000N may be the electronic device 700 illustrated in FIG. 23. The plurality of memory systems 72000A and 72999B to 72000N may constitute a RAID array. The data storage device 70000 may be implemented by a Personal Computer (PC) or a SSD.

During a program operation, the RAID controller 71000 may output program data that is output from the host to any one of the plurality of memory systems 72000A and 72999B to 72000N according to any one RAID level that is selected on the basis of RAID level information output from the host among a plurality of RAID levels.

Further, during the read operation, the RAID controller 71000 may transmit data, which is read from any one of the plurality of memory systems 72000A and 72999B to 72000N according to any one RAID level that is selected on the basis of the RAID level information output from the host among the plurality of RAID levels, to the host.

Although preferred embodiments of the present disclosure have been described for illustrative purposes, those skilled in the art will appreciate that various modifications, additions and substitutions are possible, without departing from the scope and spirit of the present disclosure as disclosed in the accompanying claims.

What is claimed is:

1. A method for operating a 3D NAND device, comprising:
providing a first die and a second die;
providing initial read levels for the first die and the second die;
changing the initial read level for the first die to a first read level based on a first offset that is calculated based on an elapsed time from a time point when a program for the first die is completed;
changing the initial read level for the second die to a second read level based on a second offset that is calculated based on an elapsed time from a time point when a program for the second die is completed; and
reading either data stored in the first die using the first read level or data stored in the second die using the second read level.

2. The method of claim 1, wherein the first die includes a first block and a second block, and
the method further comprises:
providing initial read levels for the first block and the second block,
changing the initial read level for the first block to a third read level based on a third offset that is calculated based on an elapsed time from a time point when a program for the first block is completed;
changing the initial read level for the second block to a fourth read level based on a fourth offset that is calculated based on an elapsed time from a time point when a program for the second block is completed; and
reading either data stored in the first block using the third read level or data stored in the second block using the fourth read level.

3. The method of claim 1, wherein the first die includes a first block and a second block,
the first block includes a first memory cell layer connected to a first word line, and a second memory cell layer connected to a second word line, the second memory cell layer being separated from the first word line, and
the method further comprises:
providing initial read levels for the first memory cell layer and the second memory cell layer;
changing the initial read level for the first memory cell layer to a fifth read level based on a fifth offset that is calculated based on an elapsed time from a time point when a program for the first memory cell layer is completed;
changing the initial read level for the second memory cell array to a sixth read level based on a sixth offset that is calculated based on an elapsed time from a time point when a program for the second memory cell layer is completed; and
reading either data stored in the first memory cell layer using the fifth read level or data stored in the second memory cell layer using the sixth read level.

4. The method of claim 1, wherein the first and second offsets are stored in the 3D NAND device in a form of a table.

5. The method of claim 1, wherein the first offset is stored in a defect-free block that is determined to have no defect therein.

6. The method of claim 5, wherein the first and second dies are flash memory elements, and
the defect-free block is used as a Single Level Cell (SLC) mode.

7. The method of claim 1, wherein the first offset is calculated on the basis of dispersion of a threshold voltage of the first die based on the elapsed time from the time point when the program for the first die is completed.

8. The method of claim 1, further comprising:
checking and correcting error bits of data stored in the first die; and
updating the first offset if the number of accumulated error bits is equal to or larger than a predetermined value.

9. The method of claim 1, further comprising updating the first offset if the number of programs or erases of the data stored in the first die is equal to or larger than a predetermined value.

10. The method of claim 1, wherein the first and second offsets are provided as metadata.

11. The method of claim 10, wherein the metadata comprises at least one parity bit.

12. A method for operating a 3D NAND system, comprising:
providing a first die and a second die;
providing initial read levels for the first die and the second die;
changing the initial read level for the first die to a first read level in response to a first program command that requests to program data in the first die;
changing the initial read level for the second die to a second read level in response to a second program command that requests to program data in the second die;
reading data stored in the first die with the first read level in response to a first read command that requests to read the data stored in the first die; and
reading data stored in the second die with the second read level in response to a second read command that requests to read the data stored in the second die.

13. The method of claim 12, further comprising providing an offset for the first die,
wherein the first read level is determined using the initial read level for the first die and the offset for the first die.

14. The method of claim 13, wherein the offset is loaded in a volatile memory.

15. The method of claim 12, wherein the initial read levels for the first die and the second die are equal to each other.

16. A 3D NAND system comprising:
a 3D NAND device including a plurality of dies; and
a memory controller configured to control the 3D NAND device,
wherein the memory controller is configured to correct a read level of each of the plurality of dies using an offset based on an elapsed time from a program completion time point of each die, and
the memory controller is configured to perform a read operation with the corrected read level in response to a read command.

17. The 3D NAND system of claim 16, wherein the 3D NAND device is a solid state drive (SSD).

18. The 3D NAND system of claim 16, wherein the plurality of dies include a first die and the second die, and
an offset for the first die is different from an offset for the second die.

19. The 3D NAND system of claim 16, wherein each of the plurality of dies include a plurality of blocks including a first block and a second block,
an offset for the first block is different from an offset for the second block, and
the memory controller is configured to correct a read level of each of the plurality of blocks using a corresponding offset based on an elapsed time from a program completion time point of each block.

20. The 3D NAND system of claim 16, wherein the offset is updated during a run-time when the 3D NAND device is in use.
